(19) United States
(12) Patent Application Publication
(10) Pub. No.: US 2026/0349018 A1
(43) Pub. Date: Nov. 5, 2026

(54) METHOD OF ADJUSTING TEMPERATURE OF SUBSTRATE SUPPORT AND INSPECTION APPARATUS

(71) Applicant: Tokyo Electron Limited, Tokyo (JP)

(72) Inventor: Shigeru KASAI, Nirasaki City (JP)

(21) Appl. No.: 19/710,575

(22) Filed: Jun. 17, 2026

Related U.S. Application Data
(63) Continuation of application No. PCT/JP2024/044407, filed on Dec. 16, 2024.

(30) Foreign Application Priority Data
Dec. 26, 2023 (JP) 2023-219938

(51) Int. Cl. G01R 31/00; G01R 31/28

(52) U.S. Cl. CPC G01R 31/003; G01R 31/2831

(57) ABSTRACT

A method of adjusting a substrate support temperature when inspecting devices on a substrate, wherein the substrate support includes a wafer placement surface and temperature sensors, and a temperature adjuster adjusting a wafer placement surface temperature is shared among the devices, and wherein the method includes: upon switching an inspection target device, (A) calculating a first operation amount based on a temperature measured by a preceding temperature sensor corresponding to a device which was an inspection target, and a target temperature; (B) calculating a second operation amount based on a temperature measured by a next temperature sensor corresponding to a device to be a next inspection target, and a target temperature; (C) calculating an operation amount of the temperature adjuster upon the switching by adding values from multiplying a variable α by the first operation amount and multiplying 1−α by the second operation amount; and (D) outputting the operation amount.

### CROSS-REFERENCE TO RELATED APPLICATIONS

This application is a bypass continuation application of International Patent Application No. PCT/JP2024/044407 having an international filing date of Dec. 16, 2024 and designating the United States, the international application being based upon and claiming the benefit of priority from Japanese Patent Application No. 2023-219938, filed on Dec. 26, 2023, the entire contents of which are incorporated herein by reference.

### TECHNICAL FIELD

The present disclosure relates to a method of adjusting a temperature of a substrate support and an inspection apparatus.

### BACKGROUND

Patent Document 1 discloses a placement table for placing a device as a processing target on an upper surface of the placement table, including a top plate including a wafer placement surface for the device, a heating unit configured to heat the top plate, and a plurality of temperature sensors configured to acquire a temperature of the top plate at desired measurement positions in a plan view.

### PRIOR ART DOCUMENT

### Patent Document

Patent Document 1: Japanese Patent Laid-Open Publication No. 2022-71468

### SUMMARY

According to one embodiment of the present disclosure, there is provided a method of adjusting a temperature of a substrate support that supports a substrate when inspecting a plurality of devices formed on the substrate, wherein the substrate support includes a wafer placement surface on which the substrate is placed and a plurality of temperature sensors provided along the wafer placement surface, wherein a temperature adjuster configured to adjust a temperature of the wafer placement surface is provided to be shared among the plurality of devices, wherein the method includes: upon switching of an inspection target device, (A) calculating a first operation amount by a feedback control operation, based on a temperature measured by a preceding temperature sensor, which is a temperature sensor corresponding to a target device that has been inspected, among the plurality of temperature sensors, and a target temperature; (B) calculating a second operation amount by the feedback control operation, based on a temperature measured by a next temperature sensor, which is a temperature sensor corresponding to a target device to be inspected next, among the plurality of temperature sensors, and a target temperature; (C) calculating an operation amount of the temperature adjuster upon the switching of the inspection target device by adding a value obtained by multiplying a variable α, which is 1 or less, by the first operation amount and a value obtained by multiplying 1−α by the second operation amount; and (D) outputting the operation amount of the temperature adjuster upon the switching of the inspection target device, and wherein the variable α decreases over time and a rate of decrease also decreases over time.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a perspective view schematically illustrating a configuration of an inspection apparatus according to an embodiment.

FIG. 2 is a front view schematically illustrating the configuration of the inspection apparatus according to the embodiment.

FIG. 3 is a cross-sectional view schematically illustrating a configuration of a stage.

FIG. 4 is a top view of the stage.

FIG. 5 is a block diagram illustrating an example of a configuration of a controller that controls a temperature adjuster.

FIG. 6 is a block diagram illustrating another example 1 of the configuration of the controller that controls the temperature adjuster.

FIG. 7 is a block diagram illustrating another example 2 of the configuration of the controller that controls the temperature adjuster.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a process of manufacturing a semiconductor device or the like, devices including predetermined circuit patterns are formed on a substrate such as a semiconductor wafer (hereinafter referred to as a “wafer”). The formed devices are subjected to inspection of electrical characteristics and the like and are sorted into non-defective devices and defective devices. This inspection is performed, for example, using an inspection apparatus in a state in which the substrate has not yet been divided into individual devices.

An inspection apparatus referred to as a prober or the like is provided with a substrate support including a wafer placement surface on which a substrate on which devices are formed is placed and is also installed with a probe card including a plurality of probes. During inspection, in the inspection apparatus, an electrical signal is supplied from a tester to a device via the probe in a state in which the probe is in contact with the device. Then, based on an electrical signal received by the tester from the device via the probe, it is determined whether the device is defective.

In this type of inspection apparatus, when inspecting the electrical characteristics of the device, a temperature adjuster such as a heater or a cooler and a temperature sensor are provided for purposes such as simulating mounting environments of the device. In some cases, for example, based on measurement results from the temperature sensor, a temperature of the device formed on the substrate is adjusted, that is, controlled by the temperature adjuster.

The temperature adjuster specifically adjusts a temperature of the wafer placement surface. In some cases, the wafer placement surface is divided into a plurality of regions, and temperature adjusters are provided so that the temperature can be controlled on a per-region basis. That is, a plurality of temperature adjusters may be provided. A plurality of temperature sensors may also be provided along the wafer placement surface of the substrate. When both the plurality of temperature adjusters and the plurality of temperature sensors are provided, for example, each temperature adjuster operates during inspection based on measurement results of each temperature sensor so that the temperature of the wafer placement surface is adjusted to a target temperature with in-plane uniformity.

As the number of temperature sensors and the number of temperature adjusters increase, temperature adjustment accuracy is improved, and inspection accuracy of a device is also improved. However, increasing the number of temperature adjusters significantly increases cost. In addition, since thermal influence is exerted between adjacent regions within the wafer placement surface, a degree of difficulty of temperature control for a control target also increases, and as a result, the temperature controller becomes expensive. On the other hand, using a plurality of temperature sensors can be realized with only a slight increase in cost by employing chip sensors or the like.

For this reason, in some cases, a configuration is adopted in which a plurality of temperature sensors are provided in a substrate support and temperature adjustment is performed by a single temperature adjuster. That is, a substrate support in which a plurality of temperature sensors are provided and a single temperature adjustment region is set for a wafer placement surface of a substrate may be employed.

In recent years, however, in inspection of logic integrated circuits as devices, increasing heat generation due to higher integration and higher speed of the devices has made it impossible to collectively inspect devices formed on a substrate. Therefore, standard practice is to inspect each individual device or several devices at a time.

When performing such inspection, if a plurality of temperature sensors are provided in the substrate support and the temperature is adjusted by a single temperature adjuster, an operation amount of the temperature adjuster is calculated by a feedback control operation such as a PID (Proportional-Integral-Derivative) control operation based on the temperature measured by a temperature sensor corresponding to an inspection target device and a target temperature. Then, the temperature adjuster operates based on a calculation result, and the temperature measured by the temperature sensor is adjusted to the target temperature. Temperature adjustment by the temperature adjuster affects not only the inspection target device that is generating heat but also devices not being inspected that are not generating heat. Therefore, during inspection, devices not being inspected are at a temperature lower than the target temperature.

Accordingly, after stopping power supply to a preceding inspection target device and before starting power supply to a next inspection target device, if the operation amount of the temperature adjuster is abruptly switched from being based on a temperature measurement result of a temperature sensor corresponding to the preceding inspection target device to being based on a temperature measurement result of a temperature sensor corresponding to the next inspection target device, the following phenomenon occurs. That is, the temperature measured by the temperature sensor (hereinafter referred to as a “next temperature sensor”) corresponding to the next inspection target device is not stabilized in a short time, resulting in overshoot or undershoot. In particular, when an amount of heat generated by the device is large, a time until the temperature measured by the next temperature sensor is stabilized becomes longer. If the temperature measured by the next temperature sensor is not stabilized, inspection of the next inspection target device is not performed, and thus throughput deteriorates. If a gain of the feedback control operation is reduced, it is possible to suppress the overshoot or undershoot. However, if the gain of the feedback control operation is reduced, it takes a long time until the temperature measured by the next temperature sensor reaches the target temperature, and as a result, throughput deteriorates. These issues are particularly significant in devices with large heat generation.

Therefore, a technique according to the present disclosure, in a case where a plurality of temperature sensors is installed on a substrate support and temperature control is performed by a single temperature adjuster, allows the temperature measured by the next temperature sensor to be stabilized at an early stage upon switching of an inspection target device.

Hereinafter, a method of adjusting a temperature of a substrate support and an inspection apparatus according to the present embodiment are described with reference to the drawings. In the present specification and drawings, components having substantially the same functional configuration are denoted by the same reference numerals, and redundant description thereof is omitted.

### Inspection Apparatus 1

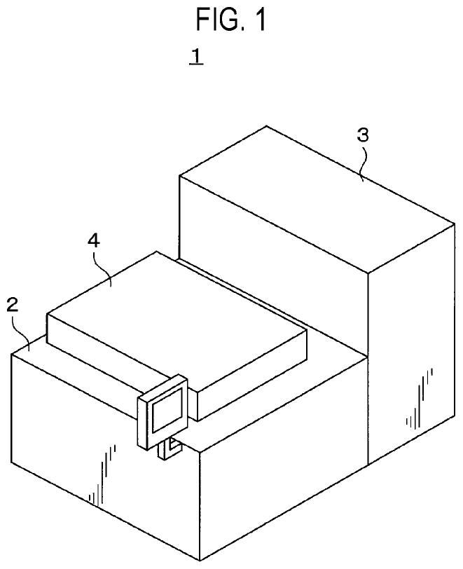

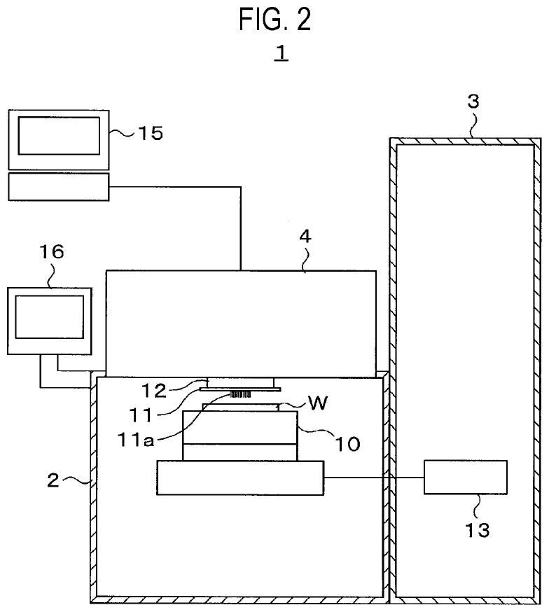

FIGS. 1 and 2 are a perspective view and a front view, respectively, schematically illustrating a configuration of an inspection apparatus 1 according to the present embodiment. In FIG. 2, a part of the inspection apparatus 1 of FIG. 1 is shown in cross section in order to show components housed in an accommodation chamber and a loader, which are described later, of the inspection apparatus 1.

The inspection apparatus 1 performs inspection of electrical characteristics of devices (not shown) formed on a wafer W serving as a substrate. Multiple devices, that is, n devices (where n is a natural number of 2 or more), are formed on the wafer W, and the inspection apparatus 1 simultaneously inspects m devices (where m is a natural number less than n) in a single inspection. In the following description, it is assumed that the number of devices becoming an inspection target in a single inspection is one. As shown in FIGS. 1 and 2, the inspection apparatus 1 includes an accommodation chamber 2 that accommodates the wafer W during inspection, a loader 3 disposed adjacent to the accommodation chamber 2, and a tester 4 disposed to cover an upper portion of the accommodation chamber.

As shown in FIG. 2, the accommodation chamber 2 is a housing having a hollow interior and includes a stage 10 serving as a substrate support that supports the wafer W. The stage 10 attracts and holds the wafer W so that a position of the wafer W relative to the stage 10 does not shift. The stage 10 is configured to be freely movable in a horizontal direction and a vertical direction. With this configuration, it is possible to adjust a relative position between a probe card 11, to be described later, and the wafer W, thereby bringing a surface electrode of the wafer W into contact with a probe 11a of the probe card 11.

In the accommodation chamber 2, the probe card 11 is disposed above the stage 10 so as to face the stage 10. The probe card 11 includes the probe 11a that electrically contacts an electrode and the like of a device formed on the wafer W. The probe card 11 is also connected to the tester 4 via an interface 12. Each probe 11a, during inspection of electrical characteristics, comes into contact with an electrode of each device formed on the wafer W, supplies power from the tester 4 to the device via the interface 12, and delivers a signal from the device to the tester 4 via the interface 12.

The loader 3 takes out the wafer W accommodated in a FOUP (Front Opening Unified Pod) (not shown), which is a transfer container, and transfers the wafer W to the stage 10 of the accommodation chamber 2. The loader 3 also receives the wafer W, for which inspection of electrical characteristics of the device has been completed, from the stage 10 and accommodates the wafer W in the FOUP.

The loader 3 includes a controller 13. The controller 13 processes computer-executable instructions that causes the inspection apparatus 1 to execute various processes described in the present disclosure. The controller 13 may be configured to control each element of the inspection apparatus 1 so as to execute the various processes described herein. In one embodiment, part or all of the controller 13 may be included in the inspection apparatus 1. The controller 13 may include a processor, a storage, and a communication interface. The controller 13 is realized, for example, by a computer. The processor may be configured to read, from the storage, a program providing logic or routines enabling various control operations, and to execute the read program to perform the various control operations. The program may be stored in advance in the storage or may be acquired via a medium when necessary. The acquired program is stored in the storage and is read from the storage and executed by the processor. The medium may be any of various computer-readable storage media or may be a communication line connected to the communication interface. The storage media may be transitory or non-transitory. The processor may be a central processing unit (CPU). The storage may include a random access memory (RAM), a read only memory (ROM), a hard disk drive (HDD), a solid state drive (SSD), or a combination thereof. The communication interface may perform communication between inspection apparatuses 1 via a communication line such as a local area network (LAN). The controller 13 may also be provided in the accommodation chamber 2.

The tester 4 includes a test board (not shown) that reproduces part of a circuit configuration of a motherboard on which devices are mounted. The test board is connected to a tester computer 15 that determines quality of a corresponding device based on a signal from the device formed on the wafer W. In the tester 4, it is possible to reproduce circuit configurations of a plurality of types of motherboards by changing the test board.

The inspection apparatus 1 also includes a user interface 16 that displays information suitable for a user and allows the user to input instructions. The user interface 16 includes, for example, an input unit such as a touch panel or a keyboard and a display such as a liquid crystal display.

In the inspection apparatus 1 including the above-described components, during inspection of electrical characteristics of the device formed on the wafer W, the tester computer 15 transmits data to the test board connected to the device via each probe 11a. Then, the tester computer 15 determines whether the transmitted data has been correctly processed by the test board based on electrical signals to the test board.

### Stage 10

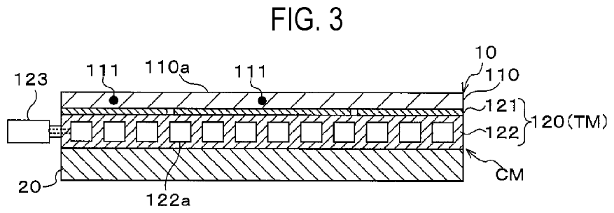

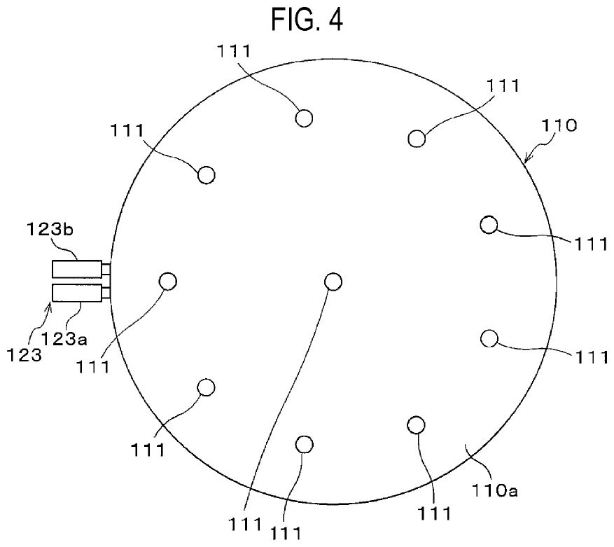

Next, a configuration of the stage 10 is described with reference to FIGS. 3 and 4. FIG. is a cross-sectional view schematically illustrating the configuration of the stage 10. FIG. 4 is a top view of the stage 10.

The stage 10 is placed on a mover (not shown) that moves the stage 10 in horizontal and vertical directions via a heat insulator 20. The heat insulator 20 is made of, for example, resin, graphite, a ceramic having low thermal conductivity, or the like.

The stage 10 includes a top plate 110 and a temperature adjustment plate 120 arranged in this order from the top.

The top plate 110 is a member whose upper surface 110a is a wafer placement surface on which the wafer W is placed. Hereinafter, the upper surface 110a of the top plate 110, which is also an upper surface of the stage 10, may be referred to as the wafer placement surface 110a. The top plate 110 is formed, for example, in a disk shape. The top plate 110 is formed thin so as to have a small heat capacity by using a material having high thermal conductivity and a high Young's modulus. By reducing the heat capacity of the top plate 110, for example, a temperature of the top plate 110 may be rapidly changed by heating using a heating plate 121 described later. As a material of the top plate 110, for example, a ceramic such as SiC or AlN is used, and when it is necessary to further reduce manufacturing cost, a metal such as copper or aluminum is used.

A plurality of temperature sensors 111 are provided along the wafer placement surface 110a of the top plate 110, as shown in FIG. 4. Specifically, for example, one temperature sensor 111 is provided at a center of the wafer placement surface 110a, and a plurality of temperature sensors 111 are provided at an outer periphery of the wafer placement surface 110a at equal intervals on a same circumference centered on the center of the wafer placement surface 110a. Each temperature sensor 111 measures a temperature of a portion of the wafer placement surface 110a where the temperature sensor 111 is provided.

The temperature adjustment plate 120 in FIG. 3 constitutes at least a part of a temperature adjuster TM that adjusts a temperature of the wafer placement surface 110a. The temperature adjustment plate 120 includes a heating plate 121 serving as a heater and a cooling plate 122.

The heating plate 121 is a member that heats the top plate 110, that is, a member that heats the wafer placement surface 110a. The heating plate 121 is formed, for example, in a disk shape. The heating plate 121 is provided, for example, between the top plate 110 and the cooling plate 122, in other words, the heating plate 121 is provided at a position closer to the wafer placement surface 110a than the cooling plate 122. The heating plate 121 incorporates a heating element (not shown). The heating element is, for example, a resistive heating element that generates heat by power supply, and the resistive heating element is formed of, for example, tungsten.

The heating element is not embedded, for example, in a center of the heating plate 121, but is embedded only in an outer periphery of the heating plate 121.

The cooling plate 122 is provided below the heating plate 121. The cooling plate 122 is a member that cools the top plate 110. The cooling plate 122 is formed, for example, in a disk shape. A flow path 122a through which a refrigerant flows is formed inside the cooling plate 122. A port 123 is connected to a side of the cooling plate 122. The port 123 includes, as shown in FIG. 4, a supply port 123a for supplying the refrigerant to the flow path 122a and a discharge port 123b for discharging the refrigerant from the flow path 122a. A fluorinated liquid, a liquid such as ethylene glycol, or a gas such as nitrogen may be used as the refrigerant.

The port 123 is connected to a chiller unit (not shown). A refrigerant, a temperature of which has been adjusted by the chiller unit, is supplied to the flow path 122a via the port 123. A cooler CM that cools the wafer placement surface 110a includes the chiller unit, the cooling plate 122, and the like.

### Controller 13

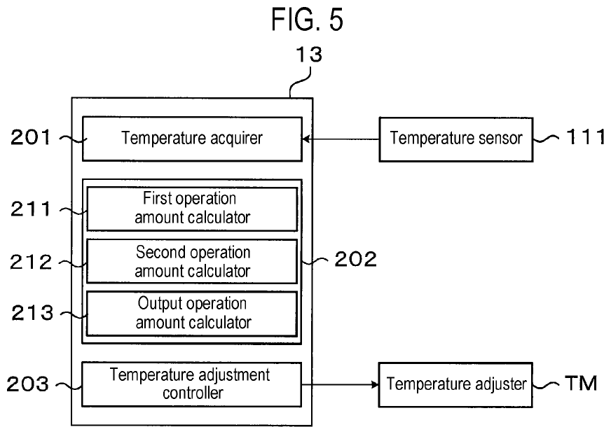

FIG. 5 is a block diagram illustrating an example of a configuration of the controller 13 that controls the temperature adjuster TM. The controller 13 includes, as shown in FIG. 5, a temperature acquirer 201, an operation amount calculator 202, and a temperature adjustment controller 203. Among the above-described parts, for example, the temperature acquirer 201 and the operation amount calculator 202 are realized by a processor such as a CPU reading and executing a program stored in a storage (not shown).

The temperature acquirer 201 acquires a temperature of a portion where a device is located on the wafer placement surface 110a, the temperature being substantially equivalent to a temperature of the device. Specifically, the temperature acquirer 201 acquires a temperature measured by the temperature sensor 111 corresponding to a temperature acquisition target device. The temperature sensor 111 corresponding to the temperature acquisition target device is, for example, a temperature sensor closest to the temperature acquisition target device.

For example, during inspection of electrical characteristics, the temperature acquirer 201 acquires the temperature measured by the temperature sensor 111 corresponding to an inspection target device, which is the temperature acquisition target device.

The temperature acquirer 201 also acquires, upon switching of the inspection target device, the temperature measured by the temperature sensor 111 corresponding to a target device that has been inspected (hereinafter sometimes referred to as a preceding temperature sensor 111p). The temperature acquirer 201 also acquires, upon the switching of the inspection target device, the temperature measured by the temperature sensor 111 corresponding to a next inspection target device (hereinafter sometimes referred to as a next temperature sensor 111n).

The operation amount calculator 202 calculates an operation amount of the temperature adjuster TM by a feedback control operation based on the temperature measured by the temperature sensor 111. Specifically, the operation amount calculator 202 calculates, by a PID control operation, an operation amount of the heating plate 121 and an operation amount of the cooler CM, based on the temperature measured by the temperature sensor 111. The operation amount of the heating plate 121 is, for example, electric power supplied to the resistive heating element. The operation amount of the cooler CM relates to at least one of a flow rate of the refrigerant or the temperature of the refrigerant, and specifically, for example, an opening degree of a flow rate control valve.

The gain in the feedback control operation (specifically, PID gain) differs between that for calculating the operation amount of the heating plate 121 and that for calculating the operation amount of the cooler CM. The gain in the feedback control operation (specifically, PID gain) may be shared among the temperature sensors 111 or may differ among the temperature sensors 111.

For example, during the inspection of electrical characteristics, the operation amount calculator 202 calculates an operation amount PVt of the temperature adjuster TM during the inspection by the feedback control operation (specifically, a PID control operation) based on the temperature measured by the temperature sensor 111 corresponding to the inspection target device and a target temperature, that is, a set temperature, and outputs the operation amount PVt to the temperature adjustment controller 203. Specifically, during the inspection of electrical characteristics, the operation amount calculator 202 calculates an operation amount PVh of the heating plate 121 during the inspection by the PID control operation, based on the temperature measured by the temperature sensor 111 corresponding to the inspection target device and the target temperature and outputs the operation amount PVh to the temperature adjustment controller 203. Similarly, the operation amount calculator 202 calculates an operation amount PVc of the cooler CM during the inspection.

The operation amount calculator 202 includes a first operation amount calculator 211, a second operation amount calculator 212, and an output operation amount calculator 213.

The first operation amount calculator 211 calculates, upon the switching of the inspection target device, a first operation amount PV1 of the temperature adjuster TM by the feedback control operation (specifically, the PID control operation), based on the temperature measured by the preceding temperature sensor 111p and a target temperature. Specifically, the first operation amount calculator 211 calculates, upon the switching of the inspection target device, a first operation amount PVh1 of the heating plate 121 by the PID control operation, based on the temperature measured by the preceding temperature sensor 111p and the target temperature. Similarly, the first operation amount calculator 211 calculates a first operation amount PVc1 of the cooler CM upon the switching of the inspection target device.

The second operation amount calculator 212 calculates, upon the switching of the inspection target device, a second operation amount PV2 of the temperature adjuster TM by the feedback control operation (specifically, the PID control operation), based on the temperature measured by the next temperature sensor 111n and a target temperature. Specifically, the second operation amount calculator 212 calculates, upon the switching of the inspection target device, a second operation amount PVh2 of the heating plate 121 by the PID control operation, based on the temperature measured by the next temperature sensor 111n and the target temperature. Similarly, the second operation amount calculator 212 calculates a second operation amount PVc2 of the cooler CM upon the switching of the inspection target device.

The output operation amount calculator 213 calculates an operation amount PVs of the temperature adjuster TM upon the switching of the inspection target device by adding a value obtained by multiplying a variable α, which is 1 or less, by the first operation amount PV1 of the temperature adjuster TM and a value obtained by multiplying (1−α) by the second operation amount PV2 of the temperature adjuster TM upon the switching of the inspection target device. That is, the output operation amount calculator 213 calculates the operation amount PVs of the temperature adjuster TM upon the switching of the inspection target device, based on the following equation:

PVs=α*PV1+(1−α)*PV2(=(PV1−PV2)*α+PV2)

The variable α decreases over time, and a rate of decrease also decreases over time. Specifically, the variable α decreases exponentially. More specifically, the variable α is defined by Equation (X) below:

α=e^{-t/T} (X)

In Equation (X), T is a predetermined time constant. The time constant T is predetermined based on an allowable time in the switching of the inspection target device, and more specifically, for example, is predetermined based on an allowable index time. In Equation (X), t is an elapsed time after completion of a preceding inspection, and specifically, is an elapsed time after completion of power supply for inspection of the preceding inspection target device in the switching of the inspection target device.

The variable α may be shared among the temperature sensors 111 or may differ among the temperature sensors 111.

The output operation amount calculator 213 calculates an operation amount PVhs of the heating plate 121 upon the switching of the inspection target device by adding a value obtained by multiplying the variable α, which is 1 or less, by the first operation amount PVh1 of the heating plate 121 and a value obtained by multiplying (1−α) by the second operation amount PVh2 of the heating plate 121 upon the switching of the inspection target device. Similarly, the output operation amount calculator 213 calculates an operation amount PVcs of the cooler CM upon the switching of the inspection target device.

Further, the output operation amount calculator 213 outputs, to the temperature adjustment controller 203, the operation amount PVs of the temperature adjuster TM upon the switching of the inspection target device, specifically, the operation amount PVhs of the heating plate 121 upon the switching of the inspection target device and the operation amount PVcs of the cooler CM upon the switching of the inspection target device. That is, in the present embodiment, the output operation amount calculator 213 also functions as an output that outputs the operation amount PVs of the temperature adjuster TM upon the switching of the inspection target device.

The temperature adjustment controller 203 controls the temperature adjuster TM based on the input operation amount PVs of the temperature adjuster TM upon the switching of the inspection target device. Specifically, the temperature adjustment controller 203 controls the heating plate 121 based on the input operation amount PVhs of the heating plate 121 upon the switching of the inspection target device and also controls the cooler CM based on the input operation amount PVcs of the cooler CM upon the switching of the inspection target device.

### Inspection Flow

Next, an example of an inspection flow by the inspection apparatus 1 is described. First, the wafer W is taken out of the FOUP of the loader 3, transferred to the stage 10, and placed on the stage 10. Subsequently, the stage 10 is moved, and the probe 11a provided above the stage comes into contact with an electrode of an inspection target device among a plurality of devices formed on the wafer W. Then, input of an inspection signal to the probe 11a is started. That is, power supply to the inspection target device is started. As a result, inspection of electrical characteristics of the inspection target device is started. Upon completion of the inspection of electrical characteristics, power supply to the device that has been the inspection target is stopped, and the probe 11a is separated from the electrode of the device. Then, the same process is performed for the next inspection target device on the wafer W. Thereafter, the above-described processes are repeated until inspection of electrical characteristics is completed for all devices.

### Temperature Control During Inspection

During the above-described inspection of electrical characteristics, the temperature of the inspection target device is required to be a desired temperature. Therefore, for example, during the inspection of electrical characteristics, the temperature acquirer 201 acquires a temperature of a portion of the wafer placement surface 110a where the inspection target device is located, which is substantially equal to the temperature of the inspection target device. Specifically, the temperature acquirer 201 acquires a temperature measured by the temperature sensor 111 corresponding to the inspection target device. Further, the operation amount calculator 202 calculates a deviation δ between the temperature acquired by the temperature acquirer 201 and the desired temperature, that is, the target temperature, calculates operation amounts PVh and PVc of the heating plate 121 and the cooler CM during the inspection by the PID control operation based on the deviation δ, and outputs the operation amounts to the temperature adjustment controller 203. Then, the temperature adjustment controller 203 controls the heating plate 121 and the cooler CM based on the operation amounts PVh and PVc of the heating plate 121 and the cooler CM during the inspection. As a result, the temperature of the inspection target device is maintained constant at the target temperature.

### Temperature Control Upon Switching of Inspection Target Device

Upon switching of an inspection target device, temperature control different from that during the inspection is performed.

Specifically, upon the switching of the inspection target device, first, power supply to a device that was an inspection target is stopped, and the temperature acquirer 201 acquires a temperature measured by the temperature sensor 111 corresponding to the device that was the inspection target, that is, the preceding temperature sensor 111p. In addition, the temperature acquirer 201 acquires a temperature measured by the temperature sensor 111 corresponding to a device to be a next inspection target, that is, the next temperature sensor 111n.

Further, the first operation amount calculator 211 calculates a deviation δp between the temperature measured by the preceding temperature sensor 111p and a target temperature, and the second operation amount calculator 212 calculates a deviation δn between the temperature measured by the next temperature sensor 111n and a target temperature. The first operation amount calculator 211 calculates first operation amounts PVh1 and PVc1 of the heating plate 121 and the cooler CM by the PID control operation based on the deviation δp. In addition, the second operation amount calculator 212 calculates second operation amounts PVh2 and PVc2 of the heating plate 121 and the cooler CM by the PID control operation based on the deviation δn.

Further, the output operation amount calculator 213 calculates an operation amount PVhs of the heating plate 121 upon the switching of the inspection target device by adding a value obtained by multiplying the variable α by the first operation amount PVh1 of the heating plate 121 and a value obtained by multiplying (1−α) by the second operation amount PVh2 of the heating plate 121, and outputs the operation amount PVhs to the temperature adjustment controller 203. Further, the output operation amount calculator 213 calculates an operation amount PVcs of the cooler CM upon the switching of the inspection target device by adding a value obtained by multiplying the variable α by the first operation amount PVc1 of the cooler CM and a value obtained by multiplying (1−α) by the second operation amount PVc2 of the cooler CM, and outputs the operation amount PVcs to the temperature adjustment controller 203.

Then, the temperature adjustment controller 203 controls the heating plate 121 and the cooler CM based on the operation amounts PVhs and PVcs of the heating plate 121 and the cooler CM upon the switching of the inspection target device.

When a first predetermined time has elapsed after the power supply was cut to the device that was the inspection target, control of the heating plate 121 and the cooler CM by the temperature adjustment controller 203 based on the operation amounts PVhs and PVcs upon the switching of the inspection target device is stopped. Instead, control of the heating plate 121 and the cooler CM by the temperature adjustment controller 203 based on the second operation amounts PVh2 and PVc2 of the heating plate 121 and the cooler CM is started. During this change of the operation amounts used for control of the heating plate 121 and the cooler CM, an integral value related to an integral control operation used for calculating the second operation amounts PVh2 and PVc2 may be maintained without being reset. That is, during the above-described change of operation amounts, an integral value held by an integrator (not shown) used to calculate the second operation amounts PVh2 and PVc2 may be maintained without being reset.

Further, when the first predetermined time has elapsed after the power supply was cut to the device that was the inspection target and when the temperature measured by the next temperature sensor 111n continuously falls within a range close to the target temperature (e.g., the target temperature ±1 degree) for a second predetermined time, the next inspection target device enters a state in which power supply thereto can be started. That is, the next inspection target device enters a state in which inspection of electrical characteristics thereof can be started.

Further, the gain in the PID control operation is the same upon switching devices for an inspection target and during inspection of the devices.

### Main Operation Effects

As described above, in the present embodiment, the temperature adjuster TM that adjusts the temperature of the wafer placement surface 110a of the stage 10 is provided to be shared among a plurality of devices, and the plurality of temperature sensors 111 are provided along the wafer placement surface 110a. In addition, in the present embodiment, upon the switching of the inspection target device, the first operation amount calculator 211 calculates the first operation amount PV1 of the temperature adjuster TM by the feedback control operation, based on the temperature measured by the preceding temperature sensor 111p and the target temperature. In addition, the second operation amount calculator 212 calculates the second operation amount PV2 of the temperature adjuster TM by the feedback control operation, based on the temperature measured by the next temperature sensor 111n and the target temperature. Then, the output operation amount calculator 213 calculates the operation amount PVs of the temperature adjuster TM upon the switching of the inspection target device by adding the value obtained by multiplying α (where α is a variable of 1 or less and decreases over time, and a rate of decrease also decreases over time) by the first operation amount PV1 of the temperature adjuster TM and the value obtained by multiplying (1−α) by the second operation amount PV2 of the temperature adjuster TM. The calculated operation amount PVs is output to the temperature adjustment controller 203 and used for the control of the temperature adjuster TM.

The target device that has been inspected, which corresponds to the preceding temperature sensor 111p, generates heat due to the power supply in the preceding inspection. However, since temperature adjustment is performed, the deviation δp between the temperature measured by the preceding temperature sensor 111p and the target temperature is small and is approximately zero. Therefore, the first operation amount PV1 of the temperature adjuster TM is also small. On the other hand, since the next inspection target device corresponding to the next temperature sensor 111n was not an inspection target in the preceding inspection, no heat is generated due to the absence of power supply. However, since a temperature adjustment same as that of the inspection target device that generates heat due to power supply is performed, the deviation δn between the temperature measured by the next temperature sensor 111n and the target temperature is relatively large. Therefore, the second operation amount PV2 of the temperature adjuster TM also becomes large. In particular, immediately after the switching of the inspection target device (specifically, immediately after starting temperature control upon the switching), the deviation δn is large, and the second operation amount PV2 of the temperature adjuster TM also becomes large.

Therefore, unlike the present embodiment, when the second operation amount PV2 of the temperature adjuster TM is continuously used upon the switching of the inspection target device for the control of the temperature adjuster TM from the beginning of the switching, the operation amount of the temperature adjuster TM becomes large in an initial stage of the switching, and a change in the temperature measured by the next temperature sensor 111n also becomes large. As a result, overshoot or undershoot occurs in the temperature measured by the next temperature sensor 111n. That is, a stabilization time of the temperature measured by the next temperature sensor 111n becomes long.

In contrast, in the present embodiment, upon the switching of the inspection target device, not the second operation amount PV2 of the temperature adjuster TM but the operation amount PVs of the temperature adjuster TM upon the switching of the inspection target device is used for the control of the temperature adjuster TM. The operation amount PVs of the temperature adjuster TM upon the switching of the inspection target device is equal to or substantially equal to the first operation amount PV1 of the temperature adjuster TM in the initial stage of the switching. Further, as described above, the first operation amount PV1 of the temperature adjuster TM is small. That is, in the present embodiment, the operation amount of the temperature adjuster TM is small in the initial stage of the switching of the inspection target device. Therefore, according to the present embodiment, in the initial stage of the switching of the inspection target device, a change in the temperature measured by the next temperature sensor 111n is also small. As a result, overshoot or undershoot is less likely to occur in the temperature measured by the next temperature sensor 111n. Further, even when the gain in the feedback control operation is increased in order to cause the temperature measured by the next temperature sensor 111n to reach the target temperature at an early stage, the operation amount PVs of the temperature adjuster TM upon the switching of the inspection target device is small in the initial stage of the switching of the inspection target device. As a result, in the present embodiment, it is possible to increase the gain in the feedback control operation. Therefore, according to the present embodiment, upon the switching of the inspection target device, the temperature measured by the next temperature sensor 111n may reach the target temperature at an early stage while suppressing overshoot or undershoot. Therefore, according to the present embodiment, in a case in which the temperature adjuster TM that adjusts the temperature of the wafer placement surface 110a of the stage 10 is provided to be shared among a plurality of devices and the plurality of temperature sensors 111 are provided along the wafer placement surface 110a, it is possible to stabilize the temperature measured by the next temperature sensor 111n at an early stage.

In the feedback control operation, gain may be shared among the temperature sensors 111, as described above. In the present embodiment, even when a strong gain, which is shared among the temperature sensors 111, is employed as the gain in the feedback control operation, it is possible to suppress overshoot or undershoot in the temperature measured by the next temperature sensor 111n regardless of which of the plurality of temperature sensors 111 corresponds to the next temperature sensor 111n. When the gain in the feedback control operation is shared among the temperature sensors 111, setting of the gain is easily performed.

Further, by setting an appropriate variable α (specifically, a time constant T) based on an allowable time in the switching of the inspection target device (specifically, for example, an allowable index time), it is possible to stabilize the temperature measured by the next temperature sensor 111n within the allowable time.

Further, as described above, when changing the operation amounts used for the control of the heating plate 121 and the cooler CM from the operation amounts PVhs and PVcs upon the switching of the inspection target device to the second operation amounts PVh2 and PVc2, an integral value related to an integral control operation used to calculate the second operation amounts PVh2 and PVc2 may be maintained without being reset. As a result, it is possible to prevent occurrence of overshoot or undershoot in the temperature measured by the next temperature sensor 111n caused by resetting of the integral value. In other words, it is possible to prevent the time until the temperature measured by the next temperature sensor 111n is stabilized from being prolonged due to the resetting of the integral value.

### Another Example 1 of Controller

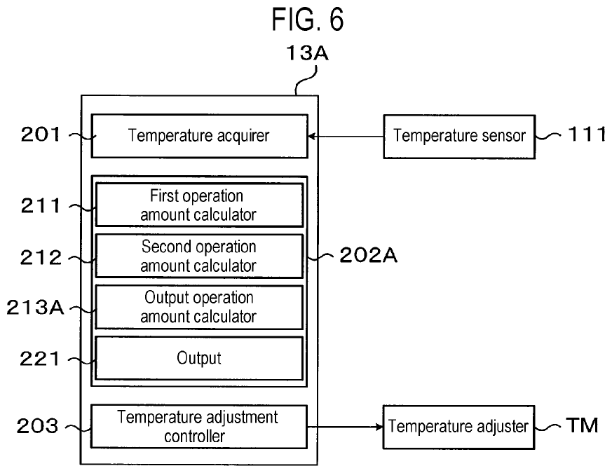

FIG. 6 is a block diagram illustrating another example 1 of the configuration of the controller that controls the temperature adjuster TM. In the operation amount calculator 202 of the controller 13 in FIG. 5, the output operation amount calculator 213 also functions as an output. In contrast, an operation amount calculator 202A of a controller 13A in FIG. 6 includes an output 221 separately from an output operation amount calculator 213A.

The output operation amount calculator 213A differs from the output operation amount calculator 213 of FIG. 5 only in that the calculated operation amount PVs of the temperature adjuster upon the switching of the inspection target device is output to the output 221. The output 221 performs base clipping on the operation amount PVs of the temperature adjuster TM upon the switching of the inspection target device so that the operation amount PVs does not fall within a dead band and outputs a base-clipped operation amount PVs′ to the temperature adjustment controller 203. Specifically, the output 221 performs the base clipping on the operation amount PVs of the temperature adjuster TM upon the switching of the inspection target device so that the operation amount PVs′ output from the output 221 does not fall within a predetermined dead band. The base clipping is a process that sets an operation amount to an upper limit value of the dead band when the operation amount is within the dead band.

As a result, it is possible to appropriately adjust a temperature of a temperature adjustment target even when a dead band, in which a change in the temperature of the temperature adjustment target does not occur, exists in an operation amount output from the output 221 and input to the temperature adjustment controller 203. Specifically, for example, when an operation amount of the cooler CM, as the operation amount of the temperature adjuster, is related to an opening degree of a flow rate control valve provided in the cooler CM, there may be a dead band in which the opening degree does not change even when the operation amount changes. In this case, by performing the base clipping as described above, it is possible to suppress a sudden change in the temperature measured by the next temperature sensor 111n caused by a rapid increase in the opening degree.

Further, the operation amount PVs′ subjected to the base clipping by the output 221 may have hysteresis. That is, the output 221 may perform base clipping on the operation amount PVs of the temperature adjuster TM upon the switching of the inspection target device so that the operation amount output from the output 221 has hysteresis. Alternatively, the output 221 may perform additional processing on the operation amount after the base clipping so that the operation amount output from the output 221 has hysteresis.

As a result, it is possible to compensate for a case in which a temperature change occurring in the temperature adjustment target differs for a same operation amount depending on whether the operation amount output from the output 221 and input to the temperature adjustment controller 203 is increasing or decreasing. Specifically, for example, when the operation amount of the cooler CM, as the operation amount of the temperature adjuster, is related to an opening degree of a flow rate control valve provided in the cooler CM, it is possible to compensate for a case in which the opening degree differs even with a same operation amount depending on whether the flow rate control valve is opening or closing. As a result, it is possible to suppress unnecessary hunting.

### Another Example 2 of Controller

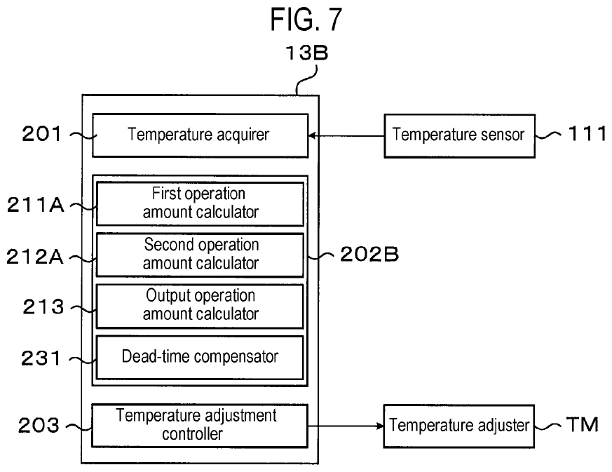

FIG. 7 is a block diagram illustrating another example 2 of the configuration of the controller that controls the temperature adjuster TM. An operation amount calculator 202B of a controller 13B in FIG. 7 includes a dead-time compensator 231 in addition to each portion of the operation amount calculator 202 of the controller 13 in FIG. 5.

The dead-time compensator 231 calculates, using a Smith method, a compensation amount corresponding to a dead time Tw included in a transfer system from input of an operation amount of the temperature adjuster TM to the temperature adjuster TM to output of a temperature measurement result by the temperature sensor 111.

Specifically, the dead-time compensator 231 calculates, as a dead-time compensation amount δh for the heating plate 121, a difference T11-T12 between a temperature T11 corresponding to an operation amount in a transfer model of the heating plate 121 that does not consider a dead time and a temperature T12 corresponding to an operation amount in a transfer model of the heating plate 121 that considers the dead time. The dead-time compensator 231 also calculates, as a dead-time compensation amount δc for the cooler CM, a difference T21-T22 between a temperature T21 corresponding to an operation amount in a transfer model of the cooler CM that does not consider the dead time and a temperature T22 corresponding to an operation amount in a transfer model of the cooler CM that considers the dead time.

For example, the dead time and the transfer model for the heating plate 121 differ among the temperature sensors 111. Specifically, when the heating element is embedded only in the outer periphery of the heating plate 121, the dead time and the transfer model for the heating plate 121 differ between the temperature sensor 111 provided at the center of the wafer placement surface 110a and the temperature sensor 111 provided at the outer periphery of the wafer placement surface 110a. Further, for example, the dead time and the dead-time compensation amount δc for the cooler CM are shared among the temperature sensors 111. Specifically, when an operation amount of the cooler CM is related to the temperature of a refrigerant, the dead time for the cooler CM exists and the dead time and the dead-time compensation amount δc are shared among the temperature sensors 111.

In this example, a first operation amount calculator 211A and a second operation amount calculator 212A calculate the first operation amount PV1 and the second operation amount PV2 of the temperature adjuster TM based on the compensation amounts calculated by the dead-time compensator 231, respectively.

Specifically, the first operation amount calculator 211A calculates the first operation amount PVh1 of the heating plate 121 based on the dead-time compensation amount δh for the heating plate 121 corresponding to a dead time for the preceding temperature sensor 111p. More specifically, the first operation amount calculator 211A calculates a corrected deviation δp′ by adding the dead-time compensation amount δh for the heating plate 121 corresponding to the dead time for the preceding temperature sensor 111p to the deviation δp between the temperature measured by the preceding temperature sensor 111p and the target temperature. The first operation amount calculator 211A then calculates the first operation amount PVh1 of the heating plate 121 by the PID control operation based on the corrected deviation δp′.

Specifically, the second operation amount calculator 212A calculates the second operation amount PVh2 of the heating plate 121 based on the dead-time compensation amount δh for the heating plate 121 corresponding to a dead time for the next temperature sensor 111n. More specifically, the second operation amount calculator 212A calculates a corrected deviation δn′ by adding the dead-time compensation amount δh for the heating plate 121 corresponding to the dead time for the next temperature sensor 111n to the deviation δn between the temperature measured by the next temperature sensor 111n and the target temperature. The second operation amount calculator 212A then calculates the second operation amount PVh2 of the heating plate 121 by the PID control operation based on the corrected deviation δn′.

Further, the first operation amount calculator 211A calculates the first operation amount PVc1 of the cooler CM based on the dead-time compensation amount δc for the cooler CM corresponding to a dead time which is shared among the temperature sensors 111. Specifically, the first operation amount calculator 211A calculates a corrected deviation δp′ by adding the dead-time compensation amount δc for the cooler CM corresponding to the dead time which is shared among the temperature sensors 111 to the deviation δp between the temperature measured by the preceding temperature sensor 111p and the target temperature. The first operation amount calculator 211A then calculates the first operation amount PVc1 of the cooler CM by the PID control operation based on the corrected deviation δp′.

Further, the second operation amount calculator 212A calculates the second operation amount PVc2 of the cooler CM based on the dead-time compensation amount δc for the cooler CM corresponding to the dead time which is shared among the temperature sensors 111. Specifically, the second operation amount calculator 212A calculates a corrected deviation δn′ by adding the dead-time compensation amount δc for the cooler CM corresponding to the dead time which is shared among the temperature sensors 111 to the deviation δn between the temperature measured by the next temperature sensor 111n and the target temperature. The second operation amount calculator 212A then calculates the second operation amount PVc2 of the cooler CM by the PID control operation based on the corrected deviation δn′.

As described above, the first operation amount calculator 211A and the second operation amount calculator 212A calculate the first operation amount PV1 and the second operation amount PV2 of the temperature adjuster TM, based on the compensation amounts calculated by the dead-time compensator 231, respectively, thereby enabling compensation for a temporal dead band.

Specifically, even when a dead time exists from input of the operation amount of the heating plate 121 to the temperature adjustment controller 203 to output of the temperature measurement result by the temperature sensor 111, it is possible to more reliably stabilize the temperature measured by the next temperature sensor 111n. Further, even when the dead time differs among the temperature sensors 111, it is possible to stabilize the temperature measured by the next temperature sensor 111n regardless of a position of the next temperature sensor 111n.

Further, even when a dead time exists from input of the operation amount of the cooler CM to the temperature adjustment controller 203 to output of the temperature measurement result by the temperature sensor 111, it is possible to more reliably stabilize the temperature measured by the next temperature sensor 111n.

It should be noted that the embodiments disclosed herein are exemplary in all aspects and are not restrictive. The above-described embodiments may be omitted, replaced, or modified in various forms without departing from the scope and spirit of the appended claims. For example, constituent elements of the above embodiments can be arbitrarily combined. From this arbitrary combination, it is needless to say that the operations and effects of the respective constituent elements related to the combination can be obtained, and other operations and other effects obvious to those skilled in the art can be obtained from the description of the present specification.

The effects described herein are illustrative or exemplary only and are not restrictive. That is, the technique of the present disclosure may obtain other effects obvious to those skilled in the art from the description herein in addition to or in place of the above effects.

Further, configuration examples described below are also within the technical scope of the present disclosure.
(1) A method of adjusting a temperature of a substrate support that supports a substrate when inspecting a plurality of devices formed on the substrate,
   wherein the substrate support includes a wafer placement surface on which the substrate is placed and a plurality of temperature sensors provided along the wafer placement surface,
   wherein a temperature adjuster configured to adjust a temperature of the wafer placement surface is provided to be shared among the plurality of devices,
   wherein the method includes:
      upon switching of an inspection target device,
      (A) calculating a first operation amount by a feedback control operation, based on a temperature measured by a preceding temperature sensor, which is a temperature sensor corresponding to a target device that has been inspected, among the plurality of temperature sensors, and a target temperature;
      (B) calculating a second operation amount by the feedback control operation, based on a temperature measured by a next temperature sensor, which is a temperature sensor corresponding to a target device to be inspected next, among the plurality of temperature sensors, and a target temperature;
      (C) calculating an operation amount of the temperature adjuster upon the switching of the inspection target device by adding a value obtained by multiplying a variable α, which is 1 or less, by the first operation amount and a value obtained by multiplying 1−α by the second operation amount; and
      (D) outputting the operation amount of the temperature adjuster upon the switching of the inspection target device, and
      wherein the variable α decreases over time and a rate of decrease also decreases over time.
(2) The method according to (1), wherein the variable α decreases exponentially.
(3) The method according to (1), wherein the variable α is defined by Equation (X) below:

α=e^{-t/T} (X)
where T is a predetermined time constant and t is an elapsed time after completion of preceding inspection.
(4) The method according to any one of (1) to (3), wherein (D) includes performing base clipping on the operation amount of the temperature adjuster upon the switching of the inspection target device so as not to fall within a dead band, and outputting a base-clipped operation amount.
(5) The method according to (4), wherein the base-clipped operation amount has hysteresis.
(6) The method of any one of (1) to (5), further including:
   (E) calculating, using a Smith method, a compensation amount corresponding to a dead time included in a transfer system from input of the operation amount of the temperature adjuster to output of a temperature measurement result by a corresponding temperature sensor among the plurality of temperature sensors,
   wherein (A) and (B) include calculating the first operation amount and the second operation amount, respectively, based on the compensation amount.
(7) The method according to (6),
   wherein (E) includes calculating a compensation amount corresponding to the dead time related to the preceding temperature sensor and a compensation amount corresponding to the dead time related to the next temperature sensor,
   wherein (A) includes calculating the first operation amount based on the compensation amount corresponding to the dead time related to the preceding temperature sensor, and
   wherein (B) includes calculating the second operation amount based on the compensation amount corresponding to the dead time related to the next temperature sensor.
(8) The method of any one of (1) to (7), wherein, when an operation amount used for control of the temperature adjuster is switched to the second operation amount from the operation amount of the temperature adjuster upon the switching of the inspection target device, an integral value related to an integral control operation used for calculating the second operation amount is maintained without being reset.
(9) An inspection apparatus for inspecting a plurality of devices formed on a substrate, the inspection apparatus including:
   a substrate support including a wafer placement surface on which the substrate is placed and a plurality of temperature sensors provided along the wafer placement surface;
   a temperature adjuster configured to adjust a temperature of the wafer placement surface and provided to be shared among the plurality of devices;
   a first operation amount calculator configured to calculate, upon switching of an inspection target device, a first operation amount by a feedback control operation, based on a temperature measured by a preceding temperature sensor, which is a temperature sensor corresponding to a target device that has been inspected, among the plurality of temperature sensors, and a target temperature;
   a second operation amount calculator configured to calculate, upon the switching of the inspection target device, a second operation amount by the feedback control operation, based on
   a temperature measured by a next temperature sensor, which is a temperature sensor corresponding to a target device to be inspected next, among the plurality of temperature sensors, and a target temperature;
   an output operation amount calculator configured to calculate an operation amount of the temperature adjuster upon the switching of the inspection target device by adding a value obtained by multiplying a variable α, which is 1 or less, by the first operation amount and a value obtained by multiplying 1−α by the second operation amount; and
   an output configured to output the operation amount of the temperature adjuster upon the switching of the inspection target device,
   wherein the variable α decreases over time and a rate of decrease also decreases over time.
(10) The inspection apparatus according to (9), wherein the variable α decreases exponentially.
(11) The inspection apparatus according to (9), wherein the variable α is defined by Equation (X) below:

α=e^{-t/T} (X)
where T is a predetermined time constant and t is an elapsed time after completion of preceding inspection.
(12) The inspection apparatus according to any one of (9) to (11), wherein the output performs base clipping on the operation amount of the temperature adjuster upon the switching of the inspection target device so as not to fall within a dead band, and outputs a base-clipped operation amount.
(13) The inspection apparatus according to (12), wherein the base-clipped operation amount has hysteresis.
(14) The inspection apparatus according to any one of (9) to (13), further including:
   a dead-time compensator configured to calculate, using a Smith method, a compensation amount corresponding to a dead time included in a transfer system from input of the operation amount of the temperature adjuster to output of a temperature measurement result by a corresponding temperature sensor among the plurality of temperature sensors,
   wherein the first operation amount calculator and the second operation amount calculator calculate the first operation amount and the second operation amount, respectively, based on the compensation amount.
(15) The inspection apparatus according to (14), wherein the dead-time compensator calculates a compensation amount corresponding to the dead time related to the preceding temperature sensor and a compensation amount corresponding to the dead time related to the next temperature sensor,
   wherein the first operation amount calculator calculates the first operation amount based on the compensation amount corresponding to the dead time related to the preceding temperature sensor, and
   wherein the second operation amount calculator calculates the second operation amount based on the compensation amount corresponding to the dead time related to the next temperature sensor.
(16) The inspection apparatus according to any one of (9) to (15), wherein, when an operation amount used for control of the temperature adjuster is switched to the second operation amount from the operation amount of the temperature adjuster upon the switching of the inspection target device, an integral value related to an integral control operation used for calculating the second operation amount is maintained without being reset.

According to the present disclosure, in a case where a common temperature adjuster is used among a plurality of devices formed on a substrate to adjust temperatures measured by temperature sensors through feedback control while inspecting some of the devices, it is possible to stabilize a temperature measured by a temperature sensor corresponding to a next inspection target device at an early stage when switching a target device for inspection.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures. α

What is claimed is:

1. A method of adjusting a temperature of a substrate support that supports a substrate when inspecting a plurality of devices formed on the substrate,
wherein the substrate support includes a wafer placement surface on which the substrate is placed and a plurality of temperature sensors provided along the wafer placement surface,
wherein a temperature adjuster configured to adjust a temperature of the wafer placement surface is provided to be shared among the plurality of devices,
wherein the method comprises:
upon switching of an inspection target device,
(A) calculating a first operation amount by a feedback control operation, based on a temperature measured by a preceding temperature sensor, which is a temperature sensor corresponding to a target device that has been inspected, among the plurality of temperature sensors, and a target temperature;
(B) calculating a second operation amount by the feedback control operation, based on a temperature measured by a next temperature sensor, which is a temperature sensor corresponding to a target device to be inspected next, among the plurality of temperature sensors, and a target temperature;
(C) calculating an operation amount of the temperature adjuster upon the switching of the inspection target device by adding a value obtained by multiplying a variable α, which is 1 or less, by the first operation amount and a value obtained by multiplying 1−α by the second operation amount; and
(D) outputting the operation amount of the temperature adjuster upon the switching of the inspection target device, and
wherein the variable α decreases over time and a rate of decrease also decreases over time.

2. The method of claim 1, wherein the variable α decreases exponentially.

3. The method of claim 1, wherein the variable α is defined by Equation (X) below:
α=e^{-t/T} (X)
where T is a predetermined time constant and t is an elapsed time after completion of preceding inspection.

4. The method of claim 3, wherein (D) includes performing base clipping on the operation amount of the temperature adjuster upon the switching of the inspection target device so as not to fall within a dead band, and outputting a base-clipped operation amount.

5. The method of claim 4, wherein the base-clipped operation amount has hysteresis.

6. The method of claim 1, further comprising:
(E) calculating, using a Smith method, a compensation amount corresponding to a dead time included in a transfer system from input of the operation amount of the temperature adjuster to output of a temperature measurement result by a corresponding temperature sensor among the plurality of temperature sensors,
wherein (A) and (B) include calculating the first operation amount and the second operation amount, respectively, based on the compensation amount.

7. The method of claim 6,
wherein (E) includes calculating a compensation amount corresponding to the dead time related to the preceding temperature sensor and a compensation amount corresponding to the dead time related to the next temperature sensor,
wherein (A) includes calculating the first operation amount based on the compensation amount corresponding to the dead time related to the preceding temperature sensor, and
wherein (B) includes calculating the second operation amount based on the compensation amount corresponding to the dead time related to the next temperature sensor.

8. The method of claim 1, wherein, when an operation amount used for control of the temperature adjuster is switched to the second operation amount from the operation amount of the temperature adjuster upon the switching of the inspection target device, an integral value related to an integral control operation used for calculating the second operation amount is maintained without being reset.

9. The method of claim 1, wherein (D) includes performing base clipping on the operation amount of the temperature adjuster upon the switching of the inspection target device so as not to fall within a dead band, and outputting a base-clipped operation amount.

10. An inspection apparatus for inspecting a plurality of devices formed on a substrate, the inspection apparatus comprising:
a substrate support including a wafer placement surface on which the substrate is placed and a plurality of temperature sensors provided along the wafer placement surface;
a temperature adjuster configured to adjust a temperature of the wafer placement surface and provided to be shared among the plurality of devices;
a first operation amount calculator configured to calculate, upon switching of an inspection target device, a first operation amount by a feedback control operation, based on a temperature measured by a preceding temperature sensor, which is a temperature sensor corresponding to a target device that has been inspected, among the plurality of temperature sensors, and a target temperature;
a second operation amount calculator configured to calculate, upon the switching of the inspection target device, a second operation amount by the feedback control operation, based on a temperature measured by a next temperature sensor, which is a temperature sensor corresponding to a target device to be inspected next, among the plurality of temperature sensors, and a target temperature;
an output operation amount calculator configured to calculate an operation amount of the temperature adjuster upon the switching of the inspection target device by adding a value obtained by multiplying a variable α, which is 1 or less, by the first operation amount and a value obtained by multiplying 1−α by the second operation amount; and
an output configured to output the operation amount of the temperature adjuster upon the switching of the inspection target device,
wherein the variable α decreases over time and a rate of decrease also decreases over time.

11. The inspection apparatus of claim 10, wherein the variable α decreases exponentially.

12. The inspection apparatus of claim 10, wherein the variable α is defined by Equation (X) below:
α=e^{-t/T} (X)
where T is a predetermined time constant and t is an elapsed time after completion of preceding inspection.

13. The inspection apparatus of claim 12, wherein the output performs base clipping on the operation amount of the temperature adjuster upon the switching of the inspection target device so as not to fall within a dead band, and outputs a base-clipped operation amount.

14. The inspection apparatus of claim 13, wherein the base-clipped operation amount has hysteresis.

15. The inspection apparatus of claim 10, further comprising:
a dead-time compensator configured to calculate, using a Smith method, a compensation amount corresponding to a dead time included in a transfer system from input of the operation amount of the temperature adjuster to output of a temperature measurement result by a corresponding temperature sensor among the plurality of temperature sensors,
wherein the first operation amount calculator and the second operation amount calculator calculate the first operation amount and the second operation amount, respectively, based on the compensation amount.

16. The inspection apparatus of claim 15, wherein the dead-time compensator calculates a compensation amount corresponding to the dead time related to the preceding temperature sensor and a compensation amount corresponding to the dead time related to the next temperature sensor,
wherein the first operation amount calculator calculates the first operation amount based on the compensation amount corresponding to the dead time related to the preceding temperature sensor, and
wherein the second operation amount calculator calculates the second operation amount based on the compensation amount corresponding to the dead time related to the next temperature sensor.

17. The inspection apparatus of claim 10, wherein, when an operation amount used for control of the temperature adjuster is switched to the second operation amount from the operation amount of the temperature adjuster upon the switching of the inspection target device, an integral value related to an integral control operation used for calculating the second operation amount is maintained without being reset.

18. The inspection apparatus of claim 10, wherein the output performs base clipping on the operation amount of the temperature adjuster upon the switching of the inspection target device so as not to fall within a dead band, and outputs a base-clipped operation amount.
